(19) United States
(12) Patent Application Publication
(10) Pub. No.: US 2009/0023234 A1
(43) Pub. Date: Jan. 22, 2009

(54) METHOD FOR MANUFACTURING LIGHT EMITTING DIODE PACKAGE

(76) Inventors: Hung-Tsung HSU, Taoyuan City (TW); Hsien-Chin Kung, Taoyuan City (TW)

Correspondence Address: HDSL, P.O. BOX 220746, CHANTILLY, VA, 20153-0746, US

(21) Appl. No.: 11/778,702

(22) Filed: Jul. 17, 2007

(51) Int. Cl. H01L 21/02

(52) U.S. Cl. 438/27; 438/26; 257/E21.499

(57) ABSTRACT

A method for manufacturing light emitting diode (LED) package first fabricates a silicon submount with at least one groove by wet etching, wherein a reflective layer, a transparent insulation layer and a metal bump are successively formed in the silicon submount. An LED die is mounted in the groove of the silicon submount. A protective glue is applied to fill the groove and provides a flat top face. A phosphor layer is formed on the flat top face by printing. The phosphor layer is formed with excellent uniformity due to the flat top face, and provides uniform wavelength conversion effect. Alternatively, a phosphor plate is manufactured in advance and selected with desired color temperature parameter. The phosphor plate with desired color temperature parameter is attached to the flat top face of the protective glue instead of printing.

### BACKGROUND OF THE INVENTION

1. Field of the Invention

The present invention relates to a method for manufacturing light emitting diode (LED) package, especially to a method for manufacturing LED package with uniform phosphor layer.

2. Description of Prior Art

Light emitting diode (LED) has the advantages of high efficiency and low cost because LED can be manufactured with direct-bandgap semiconductor and standard semiconductor manufacture process. Moreover, blue LEDs are developed with enhanced yield and power. Therefore, LED is promising for general lighting and backlight application.

FIG. 1 shows a prior art high-power LED package disclosed by U.S. patent application No. 20050274959. This high-power LED package is used to enclose a high-power LED chip 401. As shown in this figure, the high-power LED package mainly comprises a silicon submount 402, a heat-dissipation stage 409 and a focusing lens 413. The silicon submount 402 comprises a concave groove and electrode (not labeled) formed in the concave groove. The LED chip 401 is flip-chip mounted in the concave groove and electrically connected to the electrodes in the concave groove by soldering pastes 414a and 414b. The electrodes in the concave groove are electrically connected to the external electrodes 406a and 406b outside the heat-dissipation stage 409 through soldering wires 412a and 412b to power the high-power LED chip 401 by external power source. The focusing lens 413 is arranged atop the heat-dissipation stage 409 to focus the light emitted from the LED chip 401.

However, the above-mentioned prior art high-power LED package has the disadvantage:

In this package, the phosphor is mixed with epoxy and then the mixture is filled into the groove by dispenser. The uniformity of the phosphor is difficult to control and the emitted light from the high-power LED is not uniform.

### SUMMARY OF THE INVENTION

It is the object of the present invention to a method for manufacturing LED package with uniform phosphor layer.

Accordingly, the present invention provides a method for manufacturing LED package with uniform phosphor layer.

A silicon submount with at least one groove is formed by wet etching, wherein a reflective layer, a transparent insulation layer and a metal bump are successively formed in the silicon submount. An LED die is mounted in the groove of the silicon submount. A protective glue is applied to fill the groove and provides a flat top face. A phosphor layer is formed on the flat top face by printing. The phosphor layer is formed with excellent uniformity due to the flat top face, and provides uniform wavelength conversion effect.

Alternatively, a phosphor plate is manufactured in advance and selected with desired color temperature parameter. The phosphor plate with desired color temperature parameter is attached to the flat top face of the protective glue instead of printing.

### BRIEF DESCRIPTION OF DRAWING

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 shows a prior art high-power LED package.

FIG. 2 shows the flowchart of the method for manufacturing high power light emitting diode package according to the first preferred embodiment of the present invention.

FIGS. 3A to 3J show the sectional views for the light emitting diode package in each step of FIG. 2.

FIG. 4 shows a high power LED package according to the present invention.

FIG. 5 shows the flowchart of the method for manufacturing high power light emitting diode package according to the second preferred embodiment of the present invention.

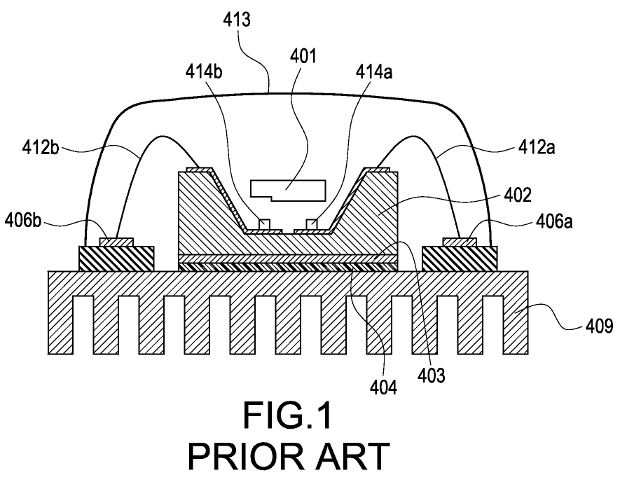

### DETAILED DESCRIPTION OF THE INVENTION

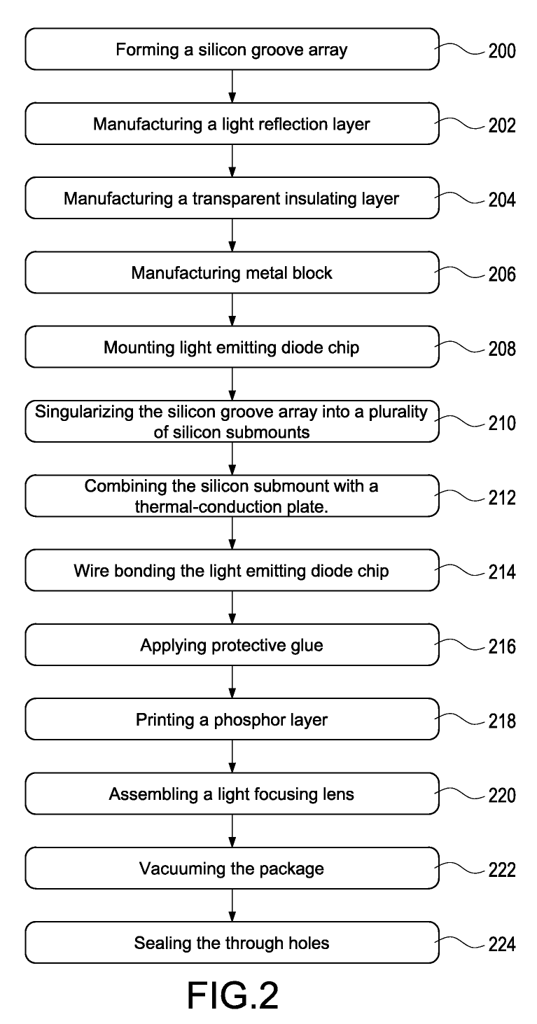

FIG. 2 shows the flowchart of the method for manufacturing high power light emitting diode package according to the first preferred embodiment of the present invention.

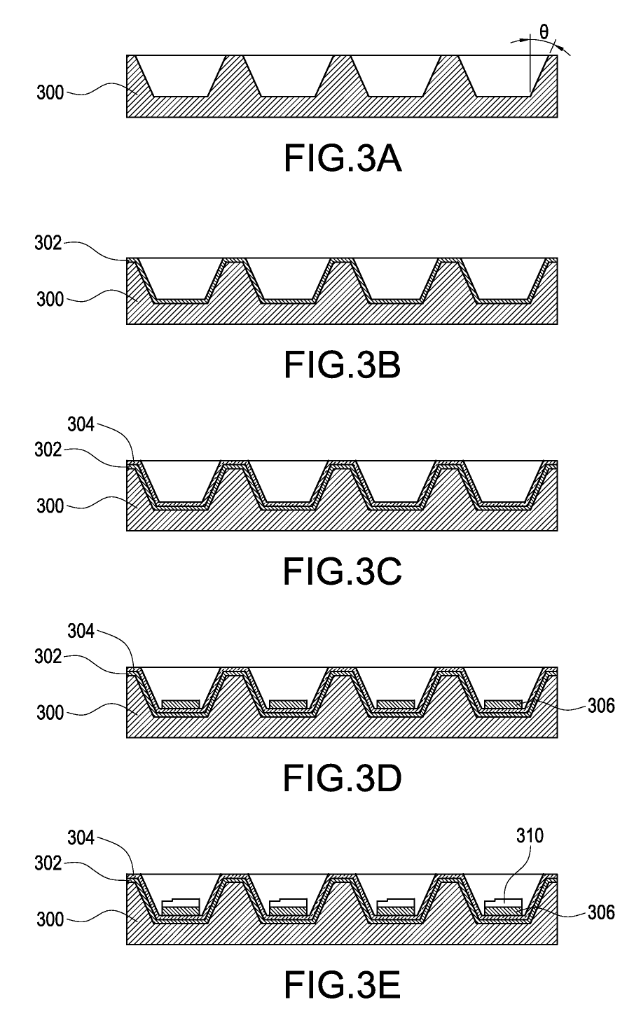

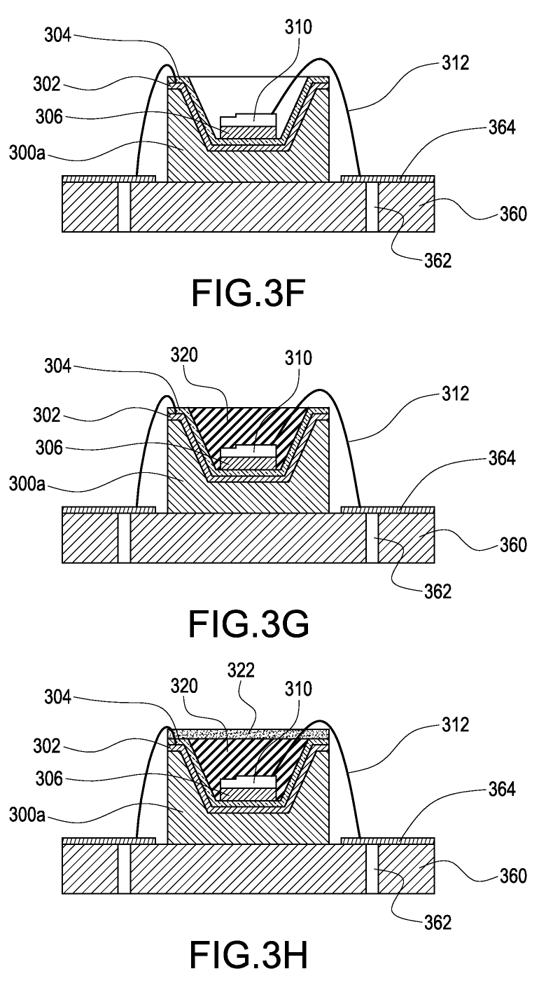

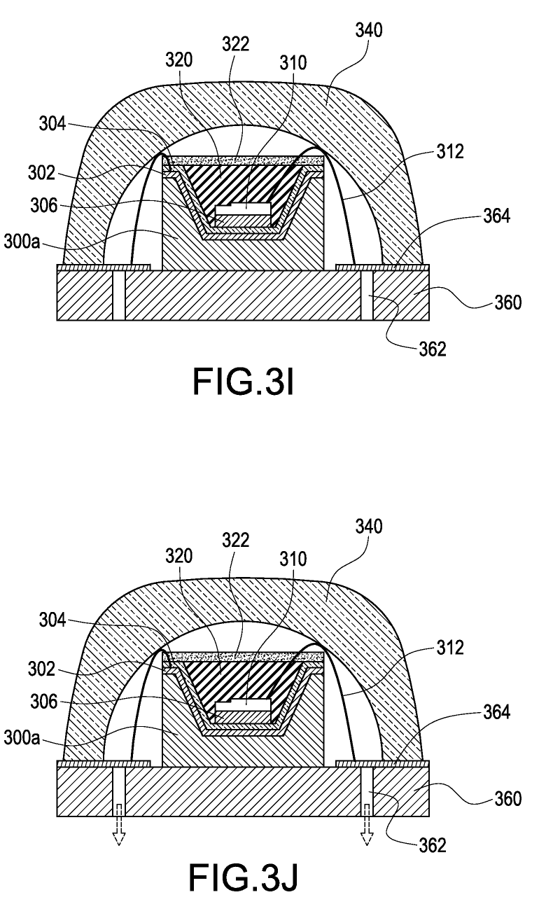

In step 200, with reference also to FIG. 3A, an anisotropic wet etching is performed on a silicon wafer to fabricate a silicon groove array 300 with a plurality of grooves. The anisotropic wet etching can be performed by KOH or TMAH solution. The silicon wafer can be an epitaxial silicon wafer and the groove has a depth of 100-300 mm and angle θ of 15-140 degree after the anisotropic wet etching.

In step 202, with reference also to FIG. 3B, a light reflection layer 302 is plated on the silicon groove array 300.

In step 204, with reference also to FIG. 3C, a transparent insulating layer 304 is formed on the light reflection layer 302.

In step 206, with reference also to FIG. 3D, a metal block 306 is formed on the transparent insulating layer 304 in each groove. The metal block 306 can be formed on the transparent insulating layer 304 by lift off process or plating process.

In step 208, with reference also to FIG. 3E, this step die-mounts an LED chip 310 on each metal block 306 and the anode (not shown) and the cathode (not shown) of the LED chip 310 are opposite to the metal block 306. The LED chip 310 is, for example, a GaN based blue LED chip and the anode and the cathode thereof are on the same side of the LED chip.

In step 210, the silicon groove array 300 die-mounted with the LED chips 310 is singularized into a plurality of silicon submounts 300a, where each silicon submount 300a comprises one or more grooves, depending on practical need.

In step 212, with reference also to FIG. 3F, the silicon submount 300a is placed on a thermal-conduction plate 360, which can be one of printed circuit board (PCB), copper plate and graphite compound plate. The thermal-conduction plate 360 further comprises external electrodes 364 corresponding to the anode and the cathode of the LED chip 310, and a plurality of through holes 362.

In step 214, with also reference also to FIG. 3F, two metal wires 312 are wire bonded to electrically connect the electrodes (anode and cathode) of the LED chip 310 to the external electrodes 364 of the thermal-conduction plate 360.

In step 216, with reference also to FIG. 3G, a protective glue 320 is applied to the resulting structure and the protective glue 320 provides an even upper surface for the silicon submount 300a. The protective glue 320 can be multiple layers of silicone, which are applied in different processing sub-steps and have different refractive indices. Therefore, the protective glue 320 also provides index matching effect by selecting silicone layers with proper index distribution.

In step 218, with reference also to FIG. 3H, a phosphor layer 322 is formed on the resulting structure by printing. According to a preferred embodiment of the present invention, the phosphor layer 322 is formed on the even upper surface of the protective glue 320 by using a scraping knife to scrape a phosphor solution on the protective glue 320 in lithography room (yellow room). The phosphor solution is prepared by mixing silicone and YAG yellow phosphor powder in 100:13 ratio. The phosphor layer 322 is formed with 50-200 micrometer thickness and has a distance of 100 micrometer with respect to the LED chip 310.

In step 220, with reference also to FIG. 31, a focusing lens 340 is assembled to the resulting structure, wherein the focusing lens 340 can be made by injection molding transparent PC plastic material or acrylic material. The focusing lens 340 can provide 3-120 degree light-focusing angle.

In step 222, with reference also to FIG. 3J, air is drawn from the through holes 362 on the thermal-conduction plate 360 to achieve a vacuum environment in a space defined by the focusing lens 340 and the thermal-conduction plate 360.

In step 224, the through holes 362 are sealed.

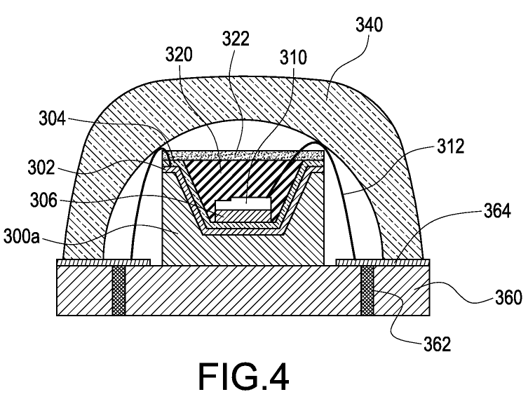

FIG. 4 shows a high power LED package according to the present invention. The LED chip 310 is not packaged in flip chip manner. Therefore, the metal block 306 can be provided between the LED chip 310 and the transparent insulating layer 304, this is benefic for high power operation. The protective glue 320 provides a smooth upper surface and a phosphor layer 322 is printed on the protective glue 320. Therefore, the high power LED package according to the present invention can provide a uniform light conversion effect. Moreover, the space defined between the focusing lens 340 and the thermal-conduction plate 360 is a vacuum space. The aging problem and the optical loss problem can be prevented.

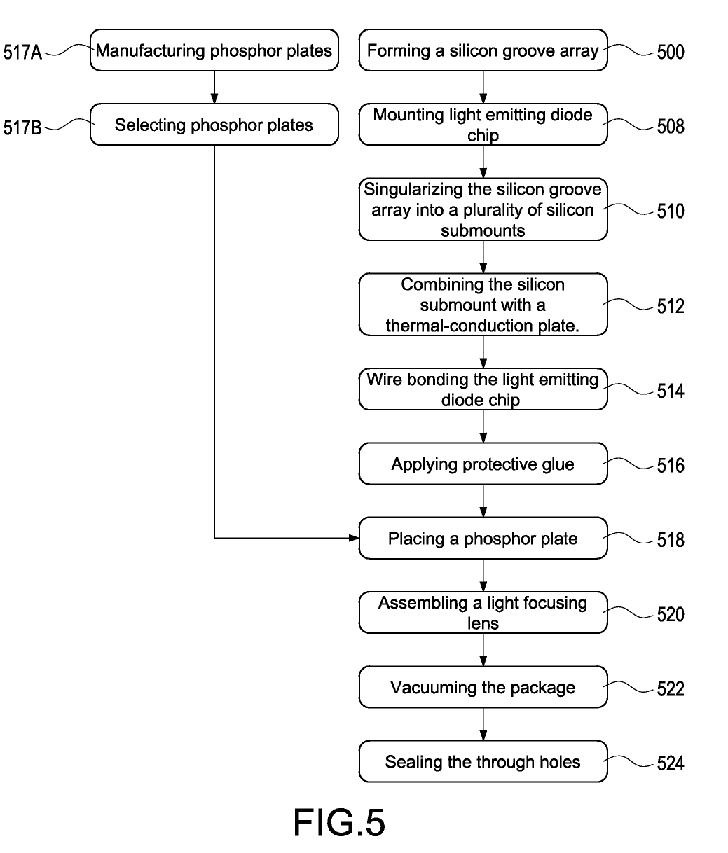

FIG. 5 shows the flowchart of the method for manufacturing high power light emitting diode package according to the second preferred embodiment of the present invention. The flowchart shown in FIG. 5 is similar to that shown in FIG. 2 except that the steps of forming reflection layer, transparent insulating layer and metal block are omitted. Moreover, the step 218 in FIG. 2 is replaced by a step of attaching phosphor plate. The phosphor plate can be manufactured in advance by mold pressing with steel mold or glass mold, and is then cured (step 517A). The cured phosphor plate is classified with predetermined color temperature parameters (step 517B). In the prior art method of manufacturing high power light emitting diode package, the phosphor is mixed with epoxy and then the phosphor mixture is applied to a cup or a groove by dispenser. Therefore, the test of color temperature can be performed only when the whole package is finished. This is cumbersome and renders instability to the manufacture process. In this preferred embodiment, the phosphor plate is cured and has fixed color temperature parameter. Therefore, the phosphor plate can be selected with predetermined color temperature parameter and then the phosphor plate with desired color temperature parameter is placed on the even surface of the protective glue to enhance yield of high power light emitting diode package.

Although the present invention has been described with reference to the preferred embodiment thereof, it will be understood that the invention is not limited to the details thereof Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. A method for manufacturing light emitting diode package, comprising:
providing a silicon groove array with a plurality of grooves;
forming a light reflection layer and a transparent insulating layer on an inner surface of each groove, respectively;
forming a metal block on the transparent insulating layer in each of the grooves;
mounting a light emitting diode chip on the metal block, wherein electrodes of the metal block are arranged on a face opposite to the metal block;
singularizing the silicon groove array into a plurality of silicon submounts, wherein each of the silicon submounts comprises at least one groove;
filling the groove with a protective glue such that the silicon submount has an even top surface; and
printing a phosphor layer on the protective glue.

2. The method for manufacturing light emitting diode package in claim 1, further comprising:
mounting the silicon submount on a thermal-conduction plate.

3. The method for manufacturing light emitting diode package in claim 2, further comprising:
arranging a focusing lens on the thermal-conduction plate to enclose the silicon submount.

4. The method for manufacturing light emitting diode package in claim 2, wherein the thermal-conduction plate is made of one of printed circuit board (PCB), copper plate and graphite compound plate.

5. The method for manufacturing light emitting diode package in claim 3, wherein the focusing lens is made of transparent PC plastic material or acrylic material.

6. The method for manufacturing light emitting diode package in claim 1, wherein the phosphor layer is printed in a yellow room.

7. The method for manufacturing light emitting diode package in claim 6, wherein the phosphor layer is formed by using a scraping knife to scrape a phosphor solution.

8. The method for manufacturing light emitting diode package in claim 7, wherein the phosphor solution is prepared by mixing a silicone and a YAG yellow phosphor powder in 100:13 ratio.

9. The method for manufacturing light emitting diode package in claim 1, wherein the silicon groove array is fabricated by wet etching a silicon wafer; and the groove has a depth of 100-300 mm and an angle of 15-140 degree.

10. The method for manufacturing light emitting diode package in claim 1, wherein the phosphor layer is formed with 50-200 micrometer and has a distance of 100 micrometer with respect to the light emitting diode chip.

11. A method for manufacturing light emitting diode package, comprising:
providing a silicon submount with at least one groove;
mounting a light emitting diode chip on the groove;
filling the groove with a protective glue such that the silicon submount has an even top surface; and
printing a phosphor layer on the protective glue.

12. The method for manufacturing light emitting diode package in claim 11, further comprising:
mounting the silicon submount on a thermal-conduction plate.

13. The method for manufacturing light emitting diode package in claim 12, further comprising:
arranging a focusing lens on the thermal-conduction plate to enclose the silicon submount.

14. The method for manufacturing light emitting diode package in claim 12, wherein the thermal-conduction plate is made of one of printed circuit board (PCB), copper plate and graphite compound plate.

15. The method for manufacturing light emitting diode package in claim 13, wherein the focusing lens is made of transparent PC plastic material or acrylic material.

16. The method for manufacturing light emitting diode package in claim 11, wherein the phosphor layer is printed in a yellow room.

17. The method for manufacturing light emitting diode package in claim 16, wherein the phosphor layer is formed by using a scraping knife to scrape a phosphor solution.

18. The method for manufacturing light emitting diode package in claim 17, wherein the phosphor solution is prepared by mixing a silicone and a YAG yellow phosphor powder in 100:13 ratio.

19. The method for manufacturing light emitting diode package in claim 11, wherein the silicon groove array is fabricated by wet etching a silicon wafer; and the groove has a depth of 100-300 mm and an angle of 15-140 degree.

20. The method for manufacturing light emitting diode package in claim 11, wherein the phosphor layer is formed with 50-200 micrometer thickness and has a distance of 100 micrometer with respect to the light emitting diode chip.

21. A method for manufacturing light emitting diode package, comprising:
providing a silicon submount with at least one groove;
mounting a light emitting diode chip on the groove;
filling the groove with a protective glue such that the silicon submount has an even top surface; and
providing a phosphor plate with a predetermined color temperature parameter on the protective glue.

22. The method for manufacturing light emitting diode package in claim 21, wherein the phosphor plate is formed by mold pressing and is cured; and the phosphor plate is then subjected to a color temperature measurement.

23. The method for manufacturing light emitting diode package in claim 21, wherein the phosphor plate is made of yellow YAG powder.

24. The method for manufacturing light emitting diode package in claim 21, wherein the protective glue is formed by applying multiple layers of silicone, wherein the multiple layers of silicone have different refractive indices to provide index matching effect.
